(19) United States
(12) Patent Application Publication
(10) Pub. No.: US 2026/0221324 A1
(43) Pub. Date: Jul. 30, 2026

(54) Dynamic Management of Superconducting Magnets

(71) Applicant: The Penn State Research Foundation, University Park, PA (US)

(72) Inventors: Federico Scurti, University Park, PA (US); Justin Schwartz, University Park, PA (US)

(21) Appl. No.: 19/142,780

(22) PCT Filed: Dec. 28, 2023
(86) PCT No.: PCT/US2023/086208

§ 371 Date: Jun. 24, 2025

Related U.S. Application Data
(60) Provisional application No. 63/435,644, filed on Dec. 28, 2022.

(51) Int. Cl. H01F 6/00; G01D 21/02; G01K 11/32; G01L 1/24; H01F 6/02; H10N 60/20

(52) U.S. Cl. CPC H01F 6/008; G01D 21/02; G01K 11/32; G01L 1/242; H01F 6/02; H10N 60/202; H10N 60/203

(57) ABSTRACT

Embodiments relate to a magnet apparatus having a winding and a magnet management unit with a sensing module configured to measure strain and/or temperature experienced by the winding. The magnet management unit includes a processor and memory having instructions stored thereon that when executed will cause the processor to detect a change in strain and/or temperature experienced by the winding. The instructions will cause the processor to calculate a reduction of transport current that, if applied to the winding, will prevent material degradation of the winding due to strain and/or heat, and eliminate or drastically reduce down-time of the magnet apparatus. The instructions will cause the processor to generate a signal indicative of the calculated reduction of transport current, the signal configured to be transmitted to a current power supply.

### CROSS-REFERENCE TO RELATED APPLICATIONS

This patent application is related to and claims the benefit of priority of U.S. provisional patent application No. 63/435,644, filed on Dec. 28, 2022, the entire contents of which is incorporated herein by reference.

### FIELD OF THE INVENTION

Embodiments relate to a magnetic apparatus configured to sense change in strain and/or temperature in windings of the magnet and calculate a reduction of transport current that will reduce the risk of or prevent material degradation of the windings while still being able to provide a supply of current so as to maintain nominal operations or minimize deviation from nominal operation of the magnetic apparatus.

### BACKGROUND OF THE INVENTION

Known techniques for monitoring irreversible material degradation of magnetic windings in superconducting magnets typically involve monitoring voltage and performing a quench protection operation that requires a complete shutdown of the magnetic apparatus, typically dumping the energy that is normally stored in the magnet as magnetic field into an external circuit. Relying on voltage monitoring can produce unreliable or inaccurate readings, and, even when the readings are reliable/accurate, the only option is to perform a quench protection operation which results in significant downtime.

### SUMMARY OF THE INVENTION

Embodiments relate to a magnetic apparatus configured to sense change in strain and/or temperature in windings of the magnet and calculate a reduction of transport current based on magnet properties and operating parameters of the magnet apparatus, as well as quantities that are measured in real-time by the sensing system embedded in the magnet, typically proportional to changes in temperature and strain of the windings. The magnet properties and operating parameters of the magnet apparatus can include inductance, current density, operating magnetic field, normal zone propagation velocity, minimum quench energy, etc. This can provide the ability to effectively and efficiently control, influence, or modulate transport current supplied to, applied to, or flowing through the winding. The amount of strain and/or heat the winding can bear without suffering material degradation can depend on current density, inductance, maximum operating magnetic field of the magnetic apparatus, normal zone propagation velocity (a normal zone is a region, area, volume, etc. of the winding that experiences an increase in temperature that has led to a local transition from the superconducting to the normal state; these normal zones lead (or at least have a propensity to) to material degradation.), etc. Thus, the techniques disclosed herein can allow for operation of the magnet apparatus while reducing the risk of or preventing material degradation experienced by the winding due to strain and/or heat. In addition, the techniques disclosed herein can allow for modulation of transport current supplied to, applied to, or flowing through the winding so as to maintain nominal operation of the magnetic apparatus (e.g., maintain operational current supply) or minimize deviation from nominal operation while also reducing the risk of or preventing material degradation. In other words, the transport current modulation techniques described herein can prevent both complete shutdown of the magnetic apparatus and material degradation of the winding.

As can be appreciated from the disclosure, embodiments of magnetic apparatus can include a subsystem that calculates a current reduction based on two categories of parameters: 1) “specs” of the magnet (magnetic properties and operating parameters) and may be referred to as magnet properties; and 2) quantities that are measured in real time that are typically proportional to temperature or strain. The subsystem can then apply a current reduction to the magnet (instead of performing an energy dump), with the current reduction being calculated and adjusted in real time based on known parameters (e.g., magnet properties and quantities that are measured live that depend on how the magnet is behaving at that precise moment in time.

This can be done to maintain nominal operation of the magnetic or minimize deviation from nominal operation. In principle, any current reduction constitutes a deviation from nominal operation (nominal operation is topically a precise amount of current (e.g. 120 A) that produces a precise amount of field (or field distribution), for example a peak field of 5 T. In some cases, a small deviation from nominal operation would not disturb the application the magnet is supporting. In other cases it would, but even in those situations, the upside is that the downtime would be of seconds (if the inventive apparatus and methods are employed) rather than of hours or days (if known or conventional apparatuses and methods are used).

An exemplary embodiment related to a magnet apparatus. The magnet apparatus can include a winding. The magnet apparatus can include a sensing module configured to measure strain and/or temperature experienced by the winding. The magnet apparatus can include a magnet management unit including a processor and memory having instructions stored thereon that when executed will cause the processor to: detect a change in strain and/or temperature experienced by the winding; calculate a reduction of transport current that, if applied to the winding, will prevent material degradation of the winding due to strain and/or heat; and generate a signal indicative of the calculated reduction of transport current, the signal configured to be transmitted to a current power supply.

In some embodiments, the instructions can cause the processor to calculate the reduction of transport current based output of the sensing module.

In some embodiments, the sensing module can be configured to generate an optical output that is proportional to the strain and/or the temperature.

In some embodiments, the magnetic apparatus can include the current power supply.

In some embodiments, the current power supply can be configured to adjust the transport current based on the calculated reduction of transport current. In some embodiments, the current power supply can be a fast current power supply.

In some embodiments, the sensing module can include an optical fiber.

In some embodiments, the magnet apparatus can be configured as a superconducting magnet.

In some embodiments, the magnet apparatus can be configured as a high-temperature superconductor (HTS) magnet.

In some embodiments, the winding can include superconducting material.

In some embodiments, the superconducting material within the magnet can be made of niobium-titanium (NbTi), niobium-tin (Nb3Sn), yttrium-barium-copper-oxide (YBa2Cu3O7-x), Bi2Sr2Ca2Cu3Ox, Bi2Sr2CalCu2Ox, and/or MgB2.

In some embodiments, the sensing module can include an optical fiber and an optical interrogator.

In some embodiments, the optical fiber can be embedded or co-wound with the winding.

In some embodiments, the sensing module can be configured to generate an optical signal based on a technique involving Fiber Bragg Grating, Rayleigh scattering, Brillouin scattering, distributed acoustic sensing, and/or Raman scattering.

In some embodiments, the optical fiber can be embedded or co-wound with the winding. The optical interrogator can be configured to measure spectral shift from the optical fiber as a function of time and position along the winding.

In some embodiments, the instructions can cause the processor to detect the change in strain and/or temperature based on the measured spectral shift being proportional to change in strain and/or temperature experienced by the winding.

In some embodiments, the instructions can cause the processor to calculate the reduction of transport current based on a predetermined time window of an optical signal detected by the optical interrogator.

In some embodiments, the instructions can cause the processor to calculate the reduction of transport current that is associated with the measured spectral shift.

In some embodiments, the reduction of transport current can, when applied, result in a current transport value that is a maximum transport current that suppresses formation or propagation of at least one normal zone but also minimizes deviation from nominal operation of the magnet apparatus.

In some embodiments, the instructions can cause the processor to calculate the reduction of transport current that corresponds to the measured spectral shift, the calculation being at a predetermined time, a continuous basis, or a periodic basis. The instructions can cause the processor to generate the signal indicative of the calculated reduction of transport current at a predetermined time, a continuous basis, or a periodic basis.

An exemplary embodiment relates to a magnet apparatus. The magnetic apparatus can include a winding. The magnetic apparatus can include an optical sensing module configured to generate an optical signal indicative of strain and/or temperature experienced by the winding. The magnetic apparatus can include a magnet management unit including a processor and memory having instructions stored thereon that when executed will cause the processor to: receive the optical signal; and generate a modulating signal for modulating transport current of a current power supply based on the optical signal.

Further features, aspects, objects, advantages, and possible applications of the present invention will become apparent from a study of the exemplary embodiments and examples described below, in combination with the Figures, and the appended claims.

### BRIEF DESCRIPTION OF THE DRAWINGS

The above and other objects, aspects, features, advantages and possible applications of the present innovation will be more apparent from the following more particular description thereof, presented in conjunction with the following drawings. Like reference numbers used in the drawings may identify like components.

FIG. 1 shows an exemplary embodiment of magnet apparatus.

FIG. 2 shows an exemplary operational diagram for an embodiment of the magnet apparatus.

FIG. 3 shows another exemplary operational diagram for an embodiment of the magnet apparatus.

FIG. 4 illustrates results of an experimental procedure showing transport current and heat pulse applied to test coil.

FIG. 5 illustrates the effect of current reduction as protective action during coil operation.

FIG. 6 shows a comparison between two identical operating scenarios with the coil being subject to the same perturbation, in one case allowing the intervention of the protection system.

FIG. 7 demonstrates thermal runaway in an experiment where no current reduction is applied.

FIG. 8 demonstrates avoidance of a thermal runaway (and consequent catastrophic failure) via activation of protective action.

FIG. 9 shows efficacy of protective action as a function of operating current.

FIG. 10 shows results of a parametric experimental study to find optimum magnitude of current reduction.

FIG. 11 shows a Bi-2223 layer wound coil with optical fiber atop the conductor (far left); a Bi-2223 layer wound coil with optical fiber between conductor edges as turn to turn insulation (middle); and a YBCO pancake coil with co-wound optical fiber SMART Conductor (far right). The insets show a detail of fiber-conductor configuration.

FIG. 12 shows a SMART conductor, wherein the left image shows a sketch of the cross section and the right image is a SEM micrograph showing optical fiber embedded in the conductor architecture.

FIG. 13A shows results from a Bi-2223 layer wound coil with fiber atop the conductor;

FIG. 13 B shows results from a Bi-2223 layer wound coil with fiber running next to conductor edge; and FIG. 13 C shows results from a YBCO pancake coil. The square wave corresponds to the heat pulse.

### DETAILED DESCRIPTION OF THE INVENTION

The following description is of exemplary embodiments that are presently contemplated for carrying out the present invention. This description is not to be taken in a limiting sense, but is made merely for the purpose of describing the general principles and features of the present invention. The scope of the present invention is not limited by this description.

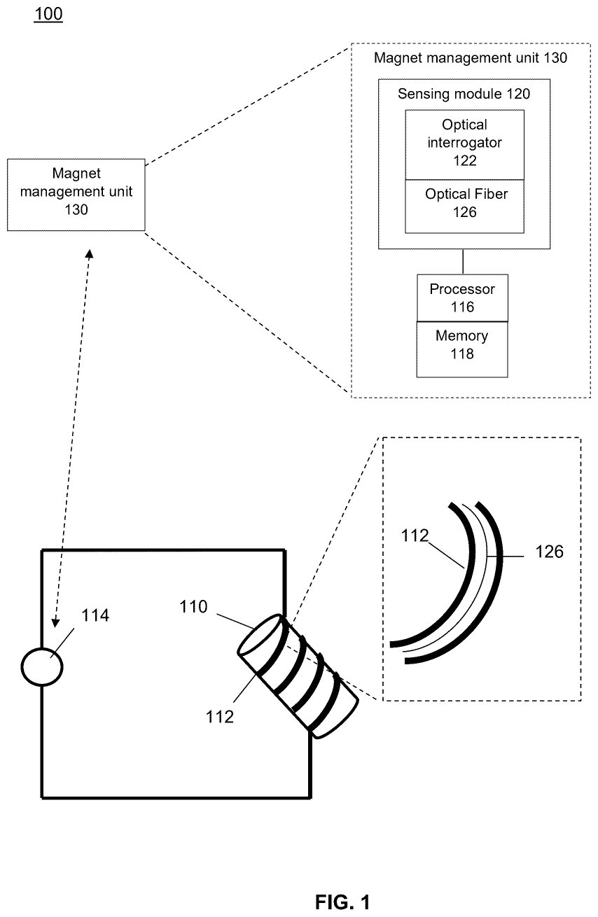

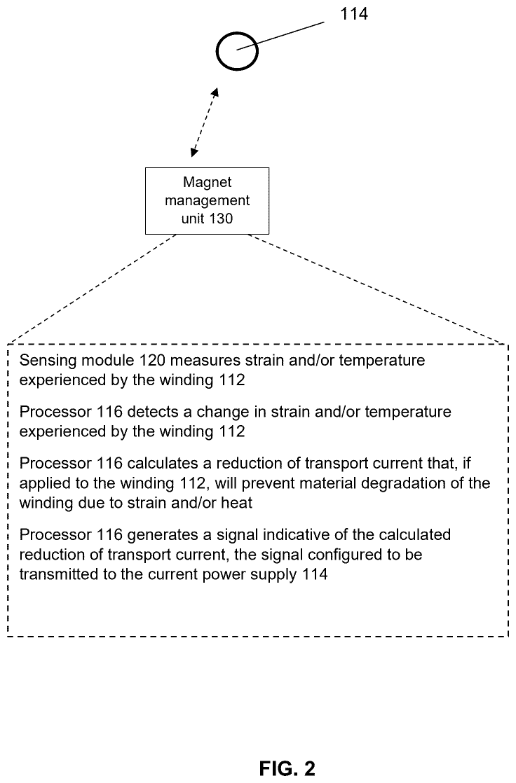

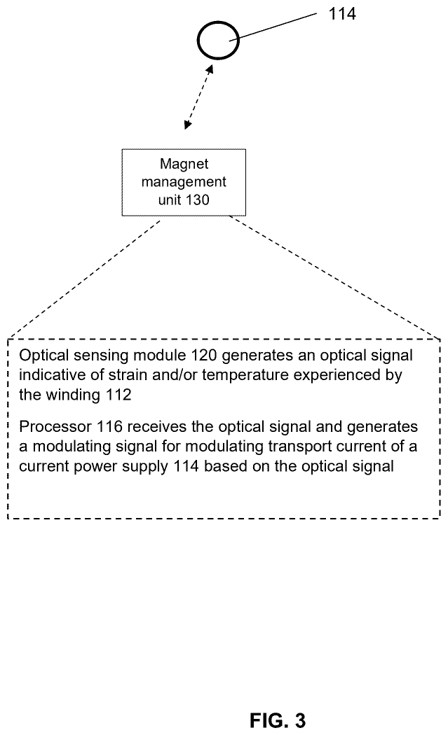

Referring to FIGS. 1-3, embodiments can relate to a magnet apparatus 100. The magnet apparatus 100 can include at least one magnetic bore 110. The magnet apparatus 100 can include at least one winding 112 wound about a periphery of the magnetic bore 110. Some embodiments can include a magnetic core within the bore 110. The core can be a component exhibiting ferromagnetic or ferrimagnetic properties. The core can include Fe, Co, Ni. Cu, Gd, tb, Fe₂O₃, NiOFe₂O₃, CuOFe₂O₃, CrO₂, etc. The core can be of any shape, size, exhibit magnetic permeability, exhibit magnetic coercivity, etc. depending on desired design criteria and technical applications of the magnetic apparatus 100. The type of material, number of cores, orientation of cores, etc. can also depend on desired design criteria and technical applications of the magnetic apparatus 100.

The winding 112 can be a component exhibiting current conducting properties. The winding 112 can include Fe, Al, Cu, Au, Ag, etc. It is contemplated for the magnetic apparatus 100 to be a superconducting magnet, and more particularly a high-temperature superconductor magnet; yet it need not be. For superconducting magnets, it is contemplated for the winding 112 to include superconducting material, such as NbTi (niobium-titanium), Nb₃Sn (niobium-tin), YBa₂Cu₃O₇₋ₓ (yttrium-barium-copper-oxide), Bi₂Sr₂Ca₂Cu₃Ox, Bi₂Sr₂Ca₁Cu₂Ox, MgB₂ for example. Other material such as copper, stainless steel, nickel-tungsten, for example, may be included with the winding 112 to provide structural or other material properties. The winding 112 can be in a form of wire, coil, tape, film, filament, etc. There can be one or more windings 112 per magnetic bore 110. The winding 112 can be of any shape, size, exhibit conductivity, etc. depending on desired design criteria and technical applications of the magnetic apparatus 100. The type of material, type of winding 112 formation, number of windings 112, pitch of the winding, how much of the magnetic bore 110 is covered by the winding 112, thickness of the winding 112, orientation of the winding 112, etc. can also depend on desired design criteria and technical applications of the magnetic apparatus 100.

As noted herein, embodiments of the magnet apparatus 100 can include one or more windings 112 with or without a core. If the magnetic apparatus 100 has a bore 110 without a core, the volume of space defined by the bore 110 can be reserved for a sample or part of the superconducting magnet application (e.g., a body/body part in MRI, a particle beam in accelerators, a chemical sample in NMR, etc.).

In general, a magnetic field is produced in the magnet bore 110 by an electric current (e.g., transport current) supplied or applied to the winding 112. If there is a core, as the electric current flows through the winding 112, the magnetic core concentrates magnetic flux. The electrical current can be supplied via a current power supply 114. The current power supply 114 can control the amount, timing, frequency, mode (direct current or alternating current), etc. of the electrical current generated and transmitted to the winding 112. An example of a current power supply 114 can be an electrical power converter that converts electrical power (e.g., voltage and/or current) as an input into a desired current as an output. The electrical power converter can be connected to an electrical power source and include AC converters, DC converters, regulators, transducers, etc. The current power supply 114 may, in some instances, include a processor and associated memory. With embodiments having a core, controlling the current to the winding 112 can be done to control the magnetic flux concentrated in the magnetic core, and thus control the magnetic field generated by the magnet apparatus 100. In some embodiments, the current power supply 114 can be a fast current power supply so as to meet the demands of superconducting operations, meet the demands of the technical applications for which the magnetic apparatus 100 is used, meet a demand posed by the inventive protection method (e.g., quick reduction in transport current), etc.

Embodiments of the magnetic apparatus 100 can include a magnet management unit 130. As will be explained herein, the magnet management unit 130 can include a processor 116 and memory 118. Other components (e.g., the current power supply 114, the sensing module 120, optical interrogator 122, etc.) can also have a processor and memory. Any of the processors disclosed herein can be part of or in communication with a machine (e.g., a computer device, a logic device, a circuit, an operating module (hardware, software, and/or firmware), etc.). The processor can be hardware (e.g., processor, integrated circuit, central processing unit, microprocessor, core processor, computer device, etc.), firmware, software, etc. configured to perform operations by execution of instructions embodied in computer program code, algorithms, program logic, control, logic, data processing program logic, artificial intelligence programming, machine learning programming, artificial neural network programming, automated reasoning programming, etc. The processor can receive, process, and/or store data related to signals measured or generated by the apparatus 100 or a component(s) of the apparatus 100.

Any of the processors disclosed herein can be a scalable processor, a parallelizable processor, a multi-thread processing processor, etc. The processor can be a computer in which the processing power is selected as a function of anticipated network traffic (e.g., data flow). The processor can include any integrated circuit or other electronic device (or collection of devices) capable of performing an operation on at least one instruction, which can include a Reduced Instruction Set Core (RISC) processor, a CISC microprocessor, a Microcontroller Unit (MCU), a CISC-based Central Processing Unit (CPU), a Digital Signal Processor (DSP), etc. The hardware of such devices may be integrated onto a single substrate (e.g., silicon “die”), or distributed among two or more substrates. Various functional aspects of the processor may be implemented solely as software or firmware associated with the processor.

Use of processors herein can include any one or combination of a Graphics Processing Unit (GPU), a Field Programmable Gate Array (FPGA), a Central Processing Unit (CPU), etc. The processor can include one or more processing or operating modules. A processing or operating module can be a software or firmware operating module configured to implement any of the functions disclosed herein. The processing or operating module can be embodied as software and stored in memory, the memory being operatively associated with the processor. A processing module can be embodied as a web application, a desktop application, a console application, etc.

The processor can include or be associated with a computer or machine readable medium. The computer or machine readable medium can include memory. Any of the memory discussed herein can be computer readable memory configured to store data. The memory can include a volatile or non-volatile, transitory or non-transitory memory, and be embodied as an in-memory, an active memory, a cloud memory, etc. Examples of memory can include flash memory, Random Access Memory (RAM), Read Only Memory (ROM), Programmable Read only Memory (PROM), Erasable Programmable Read only Memory (EPROM), Electronically Erasable Programmable Read only Memory (EEPROM), FLASH-EPROM, Compact Disc (CD)-ROM, Digital Optical Disc DVD), optical storage, optical medium, a carrier wave, magnetic cassettes, magnetic tape, magnetic disk storage or other magnetic storage devices, or any other medium which can be used to store the desired information and which can accessed by the processor.

The memory can be a non-transitory computer-readable medium. The term “computer-readable medium” (or “machine-readable medium”) as used herein is an extensible term that refers to any medium or any memory, that participates in providing instructions to the processor for execution, or any mechanism for storing or transmitting information in a form readable by a machine (e.g., a computer). Such a medium may store computer-executable instructions to be executed by a processing element and/or control logic, and data which is manipulated by a processing element and/or control logic, and may take many forms, including but not limited to, non-volatile medium, volatile medium, transmission media, etc. The computer or machine readable medium can be configured to store one or more instructions thereon. The instructions can be in the form of algorithms, program logic, etc. that cause the processor to execute any of the functions disclosed herein.

Embodiments of the memory can include a processor module and other circuitry to allow for the transfer of data to and from the memory, which can include to and from other components of a communication system. This transfer can be via hardwire or wireless transmission. The communication system can include transceivers, which can be used in combination with switches, receivers, transmitters, routers, gateways, wave-guides, etc. to facilitate communications via a communication approach or protocol for controlled and coordinated signal transmission and processing to any other component or combination of components of the communication system. The transmission can be via a communication link. The communication link can be electronic-based, optical-based, opto-electronic-based, quantum-based, etc. Communications can be via Bluetooth, near field communications, cellular communications, telemetry communications, Internet communications, etc.

Transmission of data and signals can be via transmission media. Transmission media can include coaxial cables, copper wire, fiber optics, etc. Transmission media can also take the form of acoustic or light waves, such as those generated during radio-wave and infrared data communications, or other form of propagated signals (e.g., carrier waves, digital signals, etc.).

Any of the processors can be in communication with other processors of other devices (e.g., a computer device, a computer system, a laptop computer, a desktop computer, etc.). For instance, the processor 116 of the magnet management unit 130 can be in communication with the processor of the sensing module 120 and/or the current power supply 114, the processor of the sensing module 120 can be in communication with the processor of the current power supply 114, etc. Any of the processors can have transceivers or other communication devices/circuitry to facilitate transmission and reception of wireless signals. Any of the processors can include an Application Programming Interface (API) as a software intermediary that allows two or more applications to talk to each other. Use of an API can allow software of the processor of the magnetic apparatus 100 to communicate with software of the processor of the other device(s).

The magnet management unit 130 can include a sensing module 120. As will be explained in more detail later, the sensing module 120 can be configured to measure strain and/or temperature experienced by the winding 112.

The magnet management unit 130 can include a processor 116. The magnet management unit 130 can include memory 118 having instructions stored thereon that when executed will cause the processor to execute algorithms or program logic to carry out any of the method steps discussed herein. For instance, the instructions can cause the processor 116 to detect a change in strain and/or temperature experienced by the winding 112. This can be based on measurements from the sensing module 120. The instructions can cause the processor 116 to calculate a reduction of transport current that, if applied to the winding 112, will prevent material degradation of the winding 112 due to strain and/or heat. The instructions can cause the processor 116 to generate a signal indicative of the calculated reduction of transport current. The signal can be configured to be transmitted to the current power supply 114. In some embodiments, the current power supply 114 is part of the magnetic apparatus 100. In some embodiments, the current power supply 114 is not part of the magnetic apparatus 100, but is still in communication with the magnetic apparatus 100. For instance, the processor 116 can be in communication with the processor of the current power supply 114.

In some embodiments, the instructions can cause the processor 116 to calculate the reduction of transport current based on: 1) “specs” of the magnet (magnetic properties and operating parameters) and may be referred to as magnet properties; and 2) quantities that are measured in real time by the sensing module 120. that are typically proportional to temperature or strain and indicative of the health and behavior of the magnet at that precise moment in time. Parameters falling within 2) are used to calculate the current reduction that is needed, and this current reduction is adjusted/updated/recalculated in real time based on 2) parameters, whereas parameters 1) do not change with time. The magnet properties and operating parameters of the magnet apparatus 100 can include inductance, current density, operating magnetic field, normal zone propagation velocity, minimum quench energy, etc.

One of the benefits of the magnetic apparatus 100 disclosed herein is the ability to effectively and efficiently control, influence, or modulate transport current supplied to, applied to, or flowing through the winding 112. A goal can be to reduce the risk of or prevent material degradation experienced by the winding 112 due to strain and/or heat. The amount of strain and/or heat the winding 112 can bear without suffering material degradation can be dependent on current density, inductance, maximum operating magnetic field of the magnetic apparatus 100, normal zone propagation velocity, current margin, minimum, quench energy, cooling power of the cryogenic system, requirements of the specific application, etc. A normal zone is a region, area, volume, etc. of the winding 112 that experiences an increase in temperature that has led to a local transition from the superconducting to the normal state; these normal zones lead (or at least haves a propensity to) to material degradation. Another goal can be to modulate transport current supplied to, applied to, or flowing through the winding 112 so as to maintain nominal operation of the magnetic apparatus 100 (e.g., maintain operational current supply) or minimize deviation from nominal operation while also reducing the risk of or preventing material degradation. In other words, the transport current modulation techniques described herein can prevent both complete shutdown of the magnetic apparatus 100 and material degradation of the winding 112. A particularly useful application is reducing downtime of devices and system that employ superconducting magnets. For instance, a medical device (e.g., MRI, particle accelerator for cancer therapy, etc.) use superconducting magnets. Reducing down-time from hours/days to seconds can mean treating a patient at the right time or not. Other applications include power grid devices, such as superconducting fault current limiters, or superconducting transformers or power cables, motors for civil or military propulsions (up to large MW motors for ships), etc.

In some embodiments, the current power supply 114 can be configured to adjust the transport current based on the calculated reduction of transport current. For instance, the signal indicative of the calculated reduction of transport current generated by the processor 116 can be a command signal. The processor 116 can transmit the command signal to the processor of the current power supply 114. The processor of the current power supply 114 can process the command signal and adjust the transport current accordingly.

As noted herein, the magnetic apparatus 100 can be configured as a superconducting magnet. In this regard, it is contemplated for the winding 112 to comprise superconducting material. Typically, it is necessary for the superconductor material to be held at a maximum temperature or maintained within a temperature range to exhibit superconducting properties. This can require cryogenic cooling operations to bring the winding 112 below the critical temperature of the winding material (e.g., the critical temperature of YBCO is about 90 K (−183.15° C.; −297.67° F.), while that of NbTi is 9.2 K (−263.95° C.; −443.11° F.)). The operating temperature of the winding, however, is typically well below the critical temperature of the superconducting material that is used in the winding, and could be as low as 1.8 K. For instance, the winding 112 can be cooled via liquid helium, liquid nitrogen, mechanical cooling (e.g., Gifford-McMahon Cryocooler), etc.

In some embodiments, the magnetic apparatus 100 can be configured as a high-temperature superconductor (HTS) superconducting magnet. In this regard, superconducting materials for the winding 112 will be a material that exhibits superconductivity at temperatures above 30 K (−243.15° C.; −405.67° F.).

The sensing module 120 can be configured to measure strain and/or temperature experienced by the winding 112. This can be strain and/or temperature in any one or combination of windings 112, strain and/or temperature in a portion of a winding 112, strain and/or temperature of the entire winding 112, an average strain and/or average temperature with each measurement being at different locations or times, a sum of strain and/or temperature with each measurement being at different locations or times, etc. The sensing module 120 can include a strain gauge, a temperature sensor, etc. In an exemplary embodiment, the sensing module 120 includes an optical fiber 126 and an optical interrogator 122. There can be one or more optical fibers 126 and one or more optical interrogators 122. There can be any number of optical interrogators 122 associated with (e.g., configured to measure) any number of optical fibers 126. The optical fiber 126 can include a light propagation medium (e.g., silica, plastic, etc.) having a core and a cladding that guides propagation of light via differential indexes of refraction between the cladding and the core. The optical fiber can have a suitable coating (e.g., polymeric, metallic, etc.) to protect the inner components and increase flexibility and compatibility of the fiber with the winding. It is contemplated for the optical interrogator 122 to be a Fiber Bragg Grating (FBG) interrogator; however, other optoelectronic interrogators to measure aspects of the optical fiber 126 and/or light propagating through the optical fiber 126 can be used, such as interrogators based on Rayleigh scattering, Brillouin scattering, distributed acoustic sensing, Raman scattering, etc. The interrogators can carry out the measurement of aspects of the optical fiber in time domain, in frequency domain, or a combination thereof.

The optical fiber 126 can be co-wound with the winding 112. For instance, the optical fiber can be wound about the bore 110 such that it is adjacent the winding 112, attached to the winding 112, embedded with the winding 112, or embedded within the cable, wire, tape, that makes up the winding, etc. The optical fiber 126 can be co-wound with a portion of the winding 112 or the entire winding 112. The optical fiber 126 can be oriented in the same direction (e.g., parallel with) as the winding 112 or at a different direction (e.g., perpendicular with).

With an embodiment in which the optical interrogator 122 is a Fiber Bragg Grating (FBG) interrogator, the optical interrogator 122 can include at least one Fiber Bragg Gratings (FBG) sensor. The FBG sensor can include at least one Bragg grating and at least one photodetector (e.g., photoelectric sensor, photochemical sensor, etc.). The Bragg grating can be positioned in or on the optical fiber 126 (e.g., attached to, formed within, inscribed in or on a surface, etc.) and can be either of type-I (inscribed into the fiber via UV light), or of type-II (inscribed into the fiber via a femto-second laser, also known as “damage grating”). Additionally, the grating can have various lengths, and be configured as a “long” or “ultra-long” grating.

The optical interrogator 122 includes a light source (e.g., a light emitting diode, a laser device, etc.). The optical illuminator can be configured to cause electromagnetic radiation to be incident upon a FBG sensor, for example, located in or on the optical fiber 126. More particularly, the electromagnetic radiation is caused to be incident upon the Bragg grating, reflected therefrom (e.g., reflected at the Bragg wavelength), and the reflected electromagnetic radiation is caused to be incident upon a photodetector. The photodetector can convert the readings of the reflected electromagnetic radiation into signals to be analyzed. These signals can be representative of spectral reflections from the Bragg grating—the spectral reflections being the Bragg wavelength reflected emissions). The Bragg wavelength of the Bragg grating is dependent on the strain and temperature experienced by the grating. Because the optical fiber and Bragg grating are embedded within the winding 112, changes in strain and/or temperature experienced by the winding 112 are also experienced by the optical fiber 126 and the Bragg grating. Thus, the optical interrogator 122 can be used to measure a change in strain and/or temperature experienced by the winding 112 indirectly by measuring a change in strain and/or temperature experienced by the optical fiber 126 that is embedded within or co-wound with the winding 112.

The optical interrogator 122 can be configured to measure and record spectral emissions from the optical fiber 126 at predetermined locations and predetermined times. For instance, the optical interrogator 122 can have a processor and associated memory that receives the signals from the photodetector and stores, processes, and/or analyzes the signals. A change in strain and/or temperature experienced by the Bragg grating can cause a shift in the spectrum. This spectral shift can be detected via signal processing of the processor. The spectral shift can be recorded at different locations and/or at different times. This recorded spectral shift can be used as a proxy for a measurement of a change in strain and/or temperature as a function of time and position along the winding 112. For instance, the processor can detect a change in strain and/or temperature in the winding 112 based on the measured spectral shift being proportional to change in strain and/or temperature experienced in the winding 112. In addition, or in the alternative, the processor 116 of the magnet management unit 130 can receive the signals and perform the signal processing/storage discussed above. If the processor of the optical interrogator 122 performs the signal processing, the spectral shift data can be transmitted to the processor 116 of the magnet management unit 130 for further processing, analysis, or storage. With a measurement of change in strain and/or temperature as a function of time and position along the winding 112, the processor 116 can determine if a change in strain and/or temperature has or is approaching a threshold that will result in material degradation of the winding 112. This determination can be based on whether one or more regions or areas of the winding 112 is experiencing a predetermined amount of change, an average of more than one regions or areas is experiencing a predetermined amount of change, whether the rate of change is above or below a predetermined rate, whether the change is propagating in time or space, etc. This can be done via known trend analysis techniques, regression analysis techniques, probabilistic analysis techniques, machine learning techniques, etc.

The processor can then calculate a reduction of transport current based on the spectral shift or spectral shift analysis. This calculation can be a calculated amount of reduction of transport current that, if applied to the winding 112, would reduce the risk of material degradation, prevent material degradation, improve efficiency of operation, improve lifetime of the winding, etc. As noted above, the processor 116 can perform an analysis over space and time—e.g., record and analyze spectral data from different locations along the winding 112 and at different times. With such an analysis, the calculation of reduction of transport current can be based not only on the spectral data at the time of an undesirable change in strain and/or change in temperature, but also on spectral data pertaining to a predetermined time period preceding the detected undesirable change in strain and/or temperature—e.g., the calculation can be based spatial and time evolution of an optical signal detected by the optical interrogator 122 over a period of time preceding the detected change in strain and/or temperature. This can be done to provide a more robust and intelligent response to the change in strain and/or temperature. For instance, the reduction calculation can include a determination of the amount of current reduction, the rate of current reduction (e.g., how/when the reduction of current is ramped down or up), the duration of the current reduction, etc., any one or combination of which can depend on the spatial and time evolution of the spectral data.

In some embodiments, the calculation of the reduction of transport current can be based on a threshold transport current value. This threshold current transport value can be a maximum transport current that prevents material degradation, but also maintains nominal operation of the magnet apparatus 100. As another example, this threshold transport current value can be a maximum transport current that maintains nominal operation of the magnet apparatus 100, but also suppresses formation or propagation or at least one normal zone. Nominal operation is operation of the magnet apparatus 100 that allows current to be supplied to, applied to, or flowed through the winding 112 such that the magnet apparatus 100 maintains generation of a magnetic field that is suitable for its intended technical application. Thus, the calculated reduction can be a reduction that is to or below the threshold transport current value from the instant transport current being supplied. In addition, or in the alternative, the calculation of the reduction of transport current can be based on reduction of transport current that is proportional to the measured spectral shift. Thus, even if there is no risk of material degradation via the measured spectral shift, the apparatus 100 can use the signals from the sensing module 120 as feedback to adjust the transport current in accordance with changes in the spectral shift. The calculation of the reduction of transport current that is proportional to the measured spectral shift can be done at a predetermined time, on a continuous basis, on a periodic basis, as determined by an algorithm using operational parameters as factors, etc. In addition, the generation of the signal indicative of the calculated reduction of transport current can be done at a predetermined time, on a continuous basis, on a periodic basis, as determined by an algorithm using operational parameters as factors, etc.

The calculated reduction and/or the signal generated that is indicative of the calculated reduction can be in the form of a step function, a ramp function, polynomial function, exponential function, etc. that is used by the processor 116 or the processor of the current power supply 114 to adjust the transport current being supplied to or applied to the winding 112. It is understood that other known mathematical control functions can be used in addition to the functions discussed above. For instance, the calculated reduction and/or the signal generated that is indicative of the calculated reduction can be based on moving averages, smoothing functions, upper and lower bounding bands based on statistical deviations, etc.

As noted herein, the magnet apparatus 100 and methods of use can be used to not only reduce the risk of or prevent material degradation, but it can also be used to provide more efficient and/or intelligent operation of the magnet apparatus 100. Thus, even if the magnet apparatus 100 is not experiencing or in risk of experiencing material degradation, the signals generated from the sensing module 120 measurements can be used by the magnet management unit 130 as a feedback control to modulate transport current. Thus, the sensing module 120 can be an optical sensing element discussed herein, and the sensing module 120 and/or the magnet management unit 130 can be configured to generate an optical signal indicative of strain and/or temperature experienced by the winding 112 using methods disclosed herein. The processor 116 of the magnet management unit 130 can be configured to generate a modulating signal for modulating transport current of a current power supply 114 based on the optical signal using methods disclosed herein.

### EXAMPLES

### Example 1

The apparatus 100 and method of making and using the same disclosed herein relates to means to protect superconducting magnets (SMs) from catastrophic failure. In some embodiments, the technique is based on modulating the transport current (which is what energizes the coil and stores the corresponding energy as magnetic field) only to the extent that is needed to induce a full recovery of superconducting properties, thereby avoiding catastrophic failure. The data included herein are an experimental demonstration of the effectiveness of the technique and its unique advantages over the existing systems and methods.

The conventional method to protect SMs from catastrophic failure, where present at all, consists of a total shut down of the magnet system triggered by an overvoltage, sometimes accompanied by firing of “protection heaters” that are embedded in the magnet structure and cause a spread of the normal zone to potentially the entire magnet winding; this, in theory, reduces the peak temperatures experienced locally by the magnet materials. Although these actions, if taken early during a transient, are sometimes successful at preventing a catastrophic failure in SMs wound with low temperature superconductors (LTS), they have shown to be difficult to implement and less effective in SMs wound from high temperature superconductors (HTS). In either case, these conventional protective actions cause a complete shut-down of the magnet system, which will then require several hours to a few days to be back to nominal operation, depending on the size of the magnet and the type of cryogenic cooling system. This is an especially severe downside in applications where a high frequency and wide spectrum of disturbances are expected to perturb the SMs, such as fusion reactors and superconducting motors and generators, or where the magnetic system is employed in hospitals as part of particle accelerators for cancer therapy (e.g., proton therapy), or is the essential part of a Magnetic Resonance Imaging (MRI) scanner.

Some of the advantages of this invention include:
Effectively protect all SMs from failure, both based on LTS and HTS.
Eliminate the need for (potentially frequent) system shut-downs.
Drastically reduce system down-time.
Retain partial functionality even during a “protection transient” (which quickly brings the SMs back to nominal operation).

Let us consider an example application of SMs to highlight the importance of these advantages. Consider the application of a SM as the winding of a highly efficient electric motor used for aviation (or simply propulsion). In this case, a reduction of the magnet's transport current translates into a reduction in magnetic field and, ultimately, mechanical torque (mechanical power is the product of torque and angular velocity). Correspondingly, a retention of 80% of the transport current during a protection transient would lead to a significant retention of mechanical power of the motor.

Experimental Demonstration of the technique.

A small test-coil was wound with commercial YBa₂Cu₃O₇₋ₓ superconducting wire and used as test-bed for the demonstration and characterization of the novel technique. The test-coil is shaped as a pancake coil, comprises 20 turns and an embedded heater to recreate the conditions of a fault. Additionally, the coil is equipped with an integrated optical fiber that is used to monitor the state of the coil as a function of position and time, and to trigger the protective action.

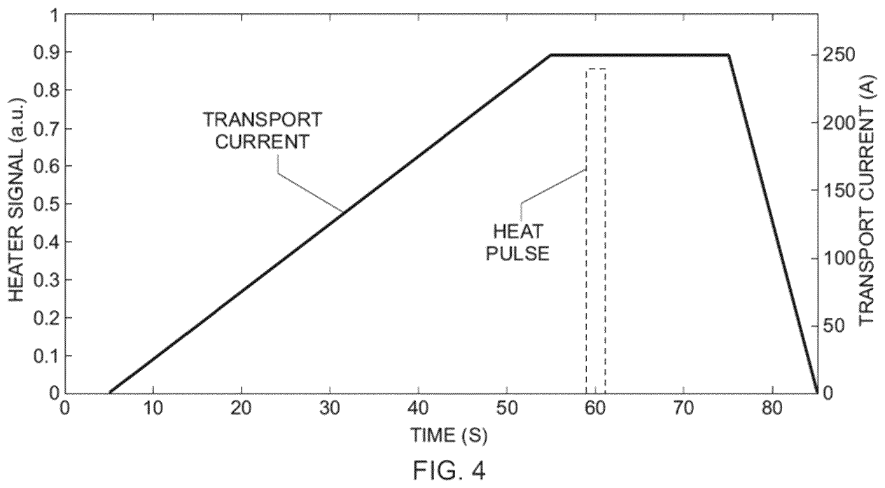

The experimental procedure used to obtain all following results includes energizing the coil with a certain transport current and, once steady state is attained, perturb it with a small heat pulse. This is illustrated in FIG. 4, where the transport current and heat pulse signals are shown for an experiment where there is no intervention of the novel protective action. The region where the transport current is constant corresponds to nominal operating conditions that are suddenly disturbed by a heat deposition (heat pulse). In the following experimental results, the response of the magnet to this perturbation is registered by the optical fiber. The optical fiber measures a quantity, the spectral shift, as a function of position within the winding and time, which is proportional to strain and temperature changes.

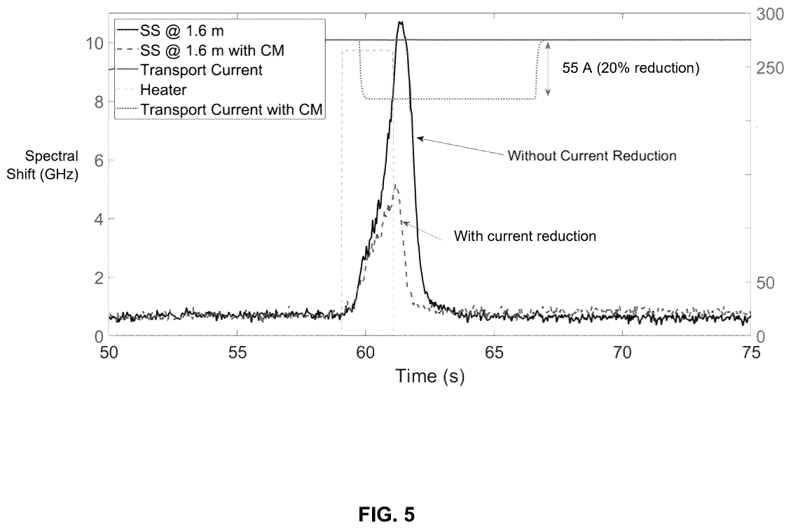

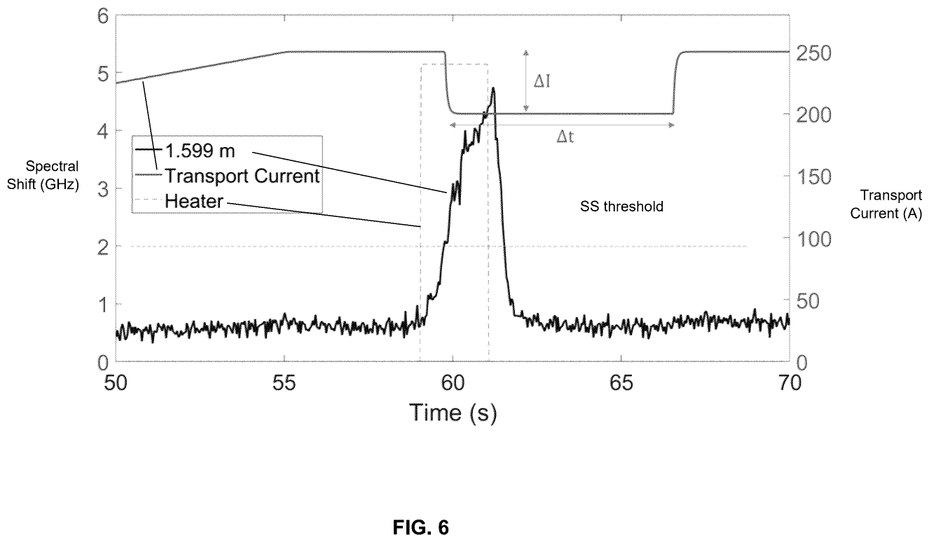

When the fault detection criterion based on the signal measured by the optical fiber is met, the protective action is applied. In these experiments, the magnitude of the transport current in operating conditions as well as the magnitude of the current reduction that is applied as part of the protective action are varied to evaluate their effect on the efficacy of the technique. To demonstrate the effect of a real-time current reduction as protective action, the test-coil is energized with a transport current of 250 A, which corresponds to about 88% of its critical current, and then perturbed with 5 W of heat for 2 s. The protective action was triggered by a 2 GHz spectral shift threshold (quantity measured by the optical fiber) and consisted of a 50 A reduction (or 20% of the operating current). The results are shown in FIG. 5. The spectral shift starts rising, indicating a transition of the superconducting coil to the normal state, until it stops at about 5 GHz during the current reduction period. In order to isolate the effect of the current reduction, a direct comparison is made by repeating the same experiment, with the same conditions of operating current and heat pulse, with and without the intervention of the protective action. The results of this comparison can be seen in FIG. 6. The spectral shift is significantly reduced by the current reduction. In particular, a 20% reduction in transport current triggered by the spectral shift criterion resulted in a 50% reduction in spectral shift. Note that in these conditions of transport current and heat pulse were not enough to cause a catastrophic failure given the highly effective cryogenic cooling and small coil size, but the protective action reduced the intensity of the transient nonetheless, therefore reducing the likelihood of causing material degradation.

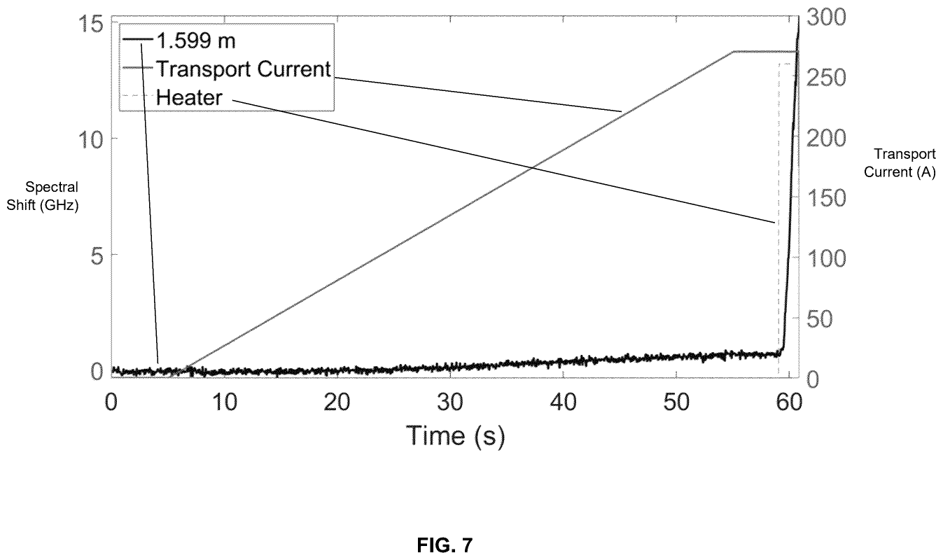

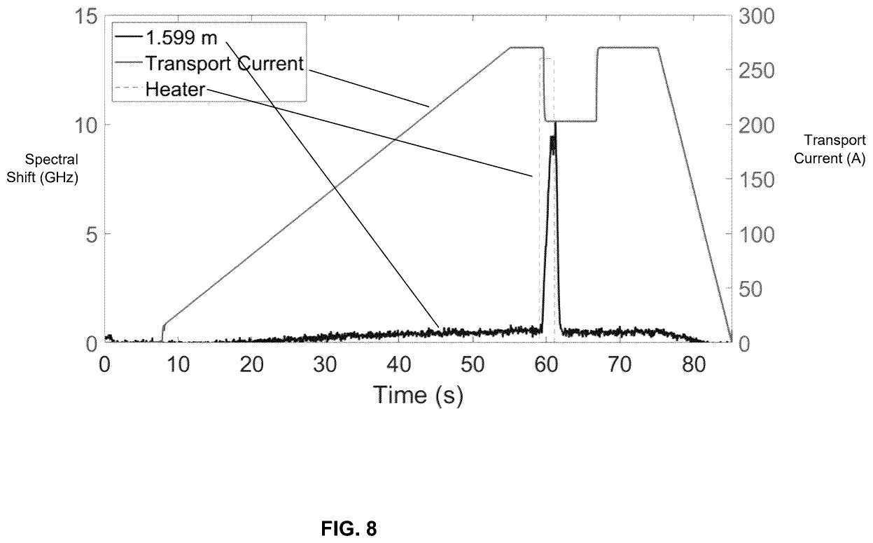

When the test-coil is subject to a stronger thermal perturbation, it quickly approaches a quench. In these experimental conditions, the intervention of the protective action clearly prevents a thermal runaway and consequent catastrophic failure. This is shown in FIGS. 7 and 8. In both cases, the operating current was set to 275 A (or 93% of the coil critical current) and a heat pulse of 6.5 W was applied for 2 s to destabilize the coil. With no current reduction, the spectral shift increases monotonically until it reaches a critical intensity, at which point the experiment is stopped to avoid catastrophic failure. By comparison, in the experiment that comprised the triggering of the current reduction, the spectral shift increase is brought to a halt right after the activation of the current modulation protective action, to then quickly return to baseline, indicating a full recovery of superconducting properties.

### Efficacy of the Technique as a Function of Operating Conditions.

The efficacy of the technique, defined as the reduction of the maximum spectral shift intensity measured during the transient that follows the instability, is studied as a function of coil operating current. A series of experiments are performed with equal conditions but different operating currents to evaluate the effect of the same % current reduction in a coil operated at various current levels (or different ratios of operating current/critical current (I/I_{c})). Table I summarizes the conditions and parameters that remain the same throughout the series of experiments and those that are varied. The SS_{threshold} is the spectral shift value above which the protective action is triggered; the magnitude of current reduction is the amount of current that is subtracted from the operating current as protective action; the current reduction timeout is the number of seconds that are waited from the moment the SS_{threshold} is no longer met to restore the operating current. At each current level (I/I_{c}), two experiments are performed: one without protective action and one with current modulation as protective action; the results are compared in terms of reduction in spectral shift intensity.

TABLE I
summary of experimental conditions used
to study the efficacy of the technique

| What's the same in all experiments | What varies |
|---|---|
| Heat pulse (5 W, 2 s) | Operating current (I/I_{c}) |
| Current ramp rates (+5 A/s, −25 A/s) | |
| SS_{threshold} (2 GHz) | |
| Magnitude of current reduction (20%) | |
| Current Reduction timeout (5 s) | |

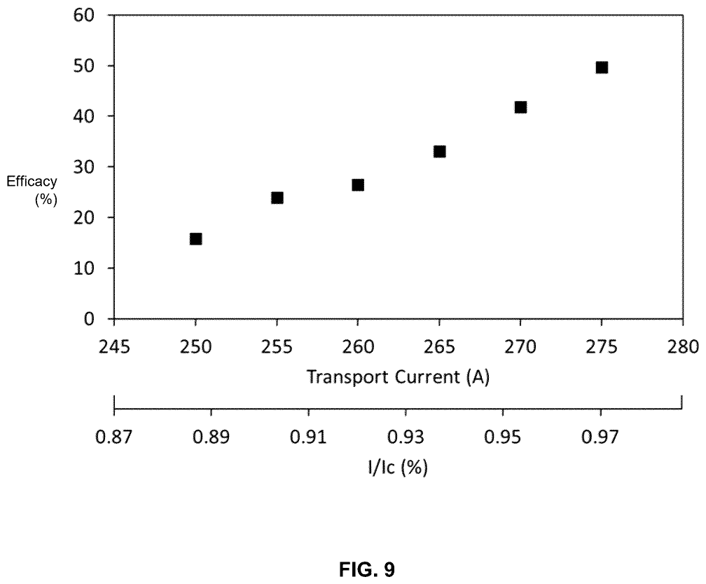

The results of the efficacy study as a function of operating current are summarized in FIG. 9. The graph shows the % reduction of spectral shift (efficacy) obtained activating the current modulation as compared to the magnitude of spectral shift experienced by the coil in the same operating conditions when no protective action is used. Results show that the efficacy increases significantly with increasing operating current, which suggests a self-regulating behavior: the efficacy of the protective action is higher when it's needed the most, e.g., when the coil is operated close to its critical current.

### Example 2

### Effect of Magnitude of Current Reduction

This study aims to find out how the efficacy of the technique changes as a function of the magnitude of the current reduction that is used as protective action. In other words, the study seeks answers to the following questions: for a certain set of operating conditions, what is the best current reduction? Is a larger current reduction always better?

Analogously to the previous study, Table II summarizes the parameters that remain the same throughout the series of experiments and those that change. In this case, the parameter that is varied is the magnitude of current reduction that is applied once the SS_{threshold} is met.

TABLE II
summary of experimental conditions used to find
sensitivity to amount of current reduction

| What's the same in all experiments | What varies |
|---|---|
| Heat pulse (5 W, 2 s) | Magnitude of current reduction |
| Current ramp rates (+5 A/s, −25 A/s) | |
| SS_{threshold} (2 GHz) | |
| Operating current (275 A or 97% I_{c}) | |
| Current Reduction timeout (5 s) | |

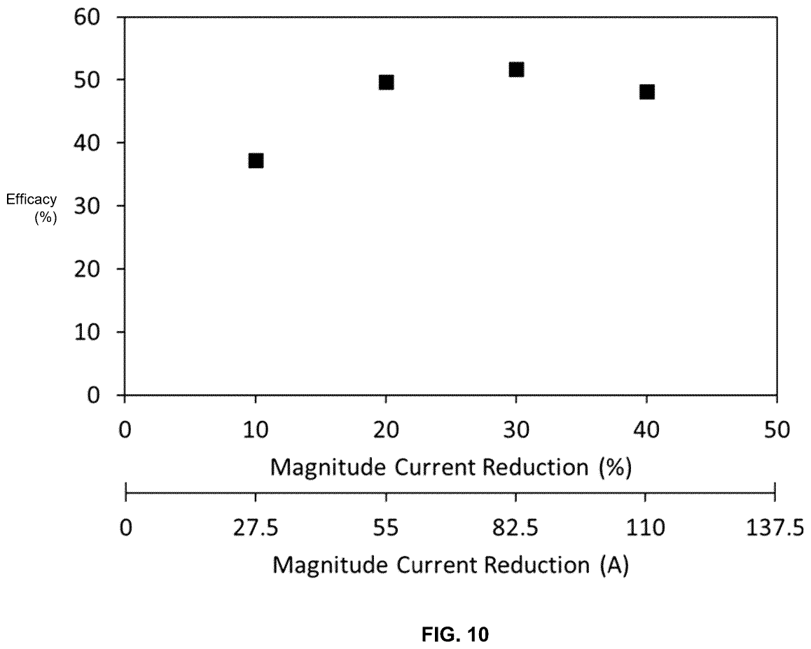

Results from this parametric set of experiments can be seen in FIG. 10, where the efficacy of the technique (defined as described above) is plotted as a function of magnitude of current reduction. These results indicate that there is an optimal magnitude of current reduction which lies between 20% and 30% of the operating current. This finding has significant implications because it demonstrates how a relatively small current reduction can be sufficient to rapidly restore superconductivity and bring the SM back to operating conditions, avoiding catastrophic failure.

### SUMMARY

These experiments demonstrate the following:
The novel protective action can avoid a catastrophic quench.
Higher current reductions are not necessarily better; there is an optimal magnitude of current reduction at given operating conditions.
The technique shows features of self-regulating behavior: effect of protective action is stronger when it's needed the most.

Note that in another embodiment of this invention, the magnitude of the current reduction is adjusted in real-time based on the measured spectral shift signal, e.g., based on the severity of the transient. By optimizing the application of the current reduction in real-time, this method will further minimize the duration and magnitude of the protection transient, in turn maximizing retention of functionality.

### Example 3

Over the last two decades, high temperature superconductors (HTS) have achieved performance and technical maturity that make them an enabling technology or an attractive solution for a number of applications like electric motors and generators, particle accelerators and fusion magnets. One of the remaining challenges that hinders a wide use of HTS and needs to be solved is quench detection, since conventional voltage based quench detection puts HTS magnets at risk.

In this work we have developed and experimentally investigated the application of Rayleigh-backscattering interrogated optical fibers (RIOF) to the detection of normal zones in superconducting magnets. Different ways to integrate optical fibers into magnets are explored and the earlier detection of RIOF compared to voltage is demonstrated.

Superconducting materials are currently being employed for the generation of magnetic fields in particle accelerators (for both high energy physics research and cancer treatment), magnetic resonance imaging (MRI), electric motors and generators, superconducting magnetic energy storage (SMES) devices, power transformers and transmission cables. While most of current applications rely on low temperature superconductors (LTS), high temperature superconductors (HTS) are emerging as materials that provide higher current densities in the presence of magnetic fields that are unachievable with LTS. This makes them an enabling technology for the generation of magnetic fields above 15 T. The most promising HTS for applications are the ceramic materials Bi2Sr2Ca1Cu2Ox (Bi-2212) and (RE)Ba2Cu3O7-y (REBCO), where RE stands for rare earth. For the next generation of Large Hadron Collider (LHC) at CERN, the High Energy-LHC (HE-LHC), the use of HTS is being considered to achieve a dipole field of 20 T that allows for a beam energy of 16.5 TeV.

Any superconducting material transitions to the normal state if any of the critical parameters is exceeded. An unintended irreversible transition to the normal state is a failure event for the superconducting device and it is referred to as quench.

To ensure safe operation, superconducting devices need to be protected from quench. The first step of the protection strategy is quench detection. Once a quench is detected, the protective action can be triggered. Protective actions typically aim at dumping the energy stored as magnetic field into another system in order to prevent joule heating from destroying the superconducting material.

### Quench Detection.

While quench detection in LTS systems has been adequately accomplished by monitoring voltage, this is not sufficient for effective quench detection in HTS magnets. The reason lies in the difference in normal zone propagation between low and high temperature superconducting materials. During the past decade, it has been extensively shown that normal zones propagate with a much lower velocity in HTS compared to LTS, by 2-3 orders of magnitude. This results into a higher local temperature at the normal zone for the same voltage and it is therefore easier to cross the temperature limit that causes irreversible material degradation and therefore irreversible loss of superconductivity. In fact, an unprotected quench is the ultimate failure that a superconducting system can undergo and causes complete loss of functionality and integrity of the device. The task of a quench protection system is to detect incipient quenches and either modify the operating conditions of the magnet or dump the energy elsewhere to avoid materials degradation and therefore allow operation to resume. Another reason that makes voltage-based quench detection ineffective, which is common to both LTS and HTS, is the fact that the voltage signal used for quench detection is, in numerous applications, heavily affected by noise. The noise can originate from the power supply that energizes the magnet and or the induction coming from time varying magnetic fields. In the presence of a noisy quench signal a stringent threshold is likely to give a false positive whereas a higher threshold increases the chance that material degradation occurs before an event can be flagged as quench. Furthermore, the earlier the detection, the larger the time budget available for the application of the protective action before irreversible material degradation. This work is about the ideation and experimental demonstration of a novel quench detection system that does not rely on voltage as the quench detection signal, instead using optical fibers as distributed sensors of temperature and strain to detect and localize normal zones in superconducting windings.

### Rayleigh Backscattering Interrogated Optical Fibers.

A number of different sensing technologies have been developed based on optical fibers, which take advantage of different physical phenomena. One of the most used techniques is Fiber Bragg Gratings (FBG). In FBG sensors, gratings are artificially inscribed on an optical fiber to create a pattern of indices of refraction, whose period determines the wavelength of the backscattered photons (Bragg wavelength). A change in strain or temperature at the location of the grating creates a shift in the Bragg wavelength that can be related to temperature or strain changes. Because of the need to inscribe gratings, FBGs are intrinsically point sensors. Another interrogation technique that uses single-mode telecommunication grade optical fibers is Rayleigh backscattering. The easiest way to think of a Rayleigh backscattering interrogated optical fiber (RIOF) is to consider it as having a random distribution of FBGs with a random fluctuation of grating periods. In this case, the pattern in index of refraction is continuous along the fiber length rather than artificially produced by inscribing gratings—e.g., it is naturally occurring due to density fluctuations, vacancies, voids, impurities and other defects. From the perspective of photon interactions with matter, all of the aforementioned defects are scattering centers for Rayleigh scattering. Some fraction of the scattering events result in backscattering and are used to calculate the spectral shift as a function of length on the fiber. The optical system required to measure the spectral shift is based on Swept Wavelength Interferometry (SWI) 14, and the signal measured by RIOF is spectral shift and depends on temperature and strain changes in the fiber.

Sensors Implementation into Magnets.

To use optical fibers to sense normal zones in superconducting magnets, the fiber must be integrated into the magnet system in intimate contact with the conductor. A first integration technique is to co-wind or embed optical fibers with superconducting wire. Another integration method we have pursued is integrating optical fibers into REBCO superconducting wires, making a self-monitoring, SMART coated conductor.

### Co-Wound or Embedded Fiber Approach.

In this case optical fibers have been co-wound with superconducting coils in different configurations. Layer wound coils have been fabricated and characterized for quench detection with the optical fiber running atop the conductor and next to the conductor edge, serving also as a turn to turn insulation. The conductor used to wind these coils is the HTS Bi2Sr2Ca2Cu3Ox/Ag-alloy (Bi2223). Pancake coils have been wound with YBCO with Kapton as turn to turn insulation.

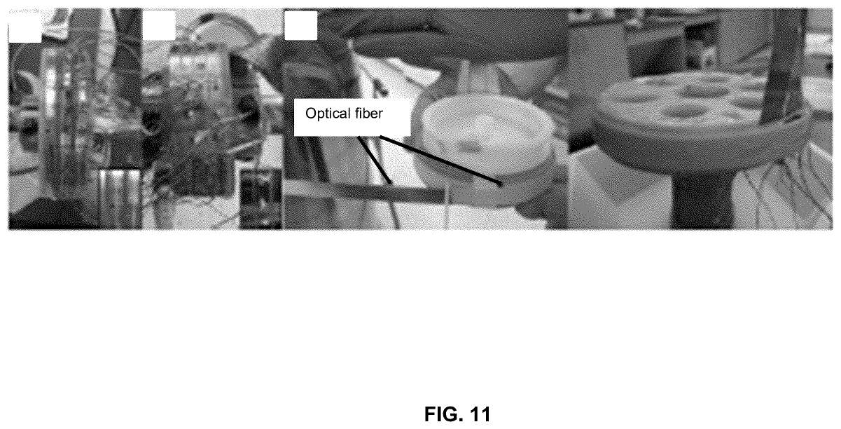

In these coils the optical fiber is attached to the insulation that is slightly wider than the conductor and is in contact with the conductor edge. All coils are depicted in FIG. 11. In addition to the optical fibers, all coils are instrumented with voltage taps and an embedded heater attached to the conductor surface to release a thermal perturbation that initiates normal zones.

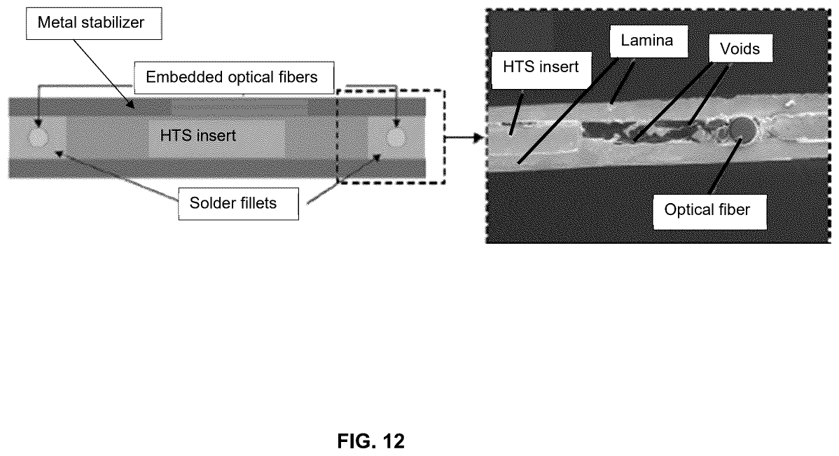

As an alternative approach to co-winding optical fibers with superconducting wire, an optical fiber has been directly embedded into the conductor architecture. A self-monitoring superconducting wire has been created, manufactured and characterized, integrating an optical fiber into American Superconductor Corporation's (AMSC) YBCO coated conductor. The typical YBCO conductor architecture consists of a strong Ni—W substrate coated with a stack of different buffer layers that provide the texture for the top YBCO layer. The YBCO layer is then coated with silver and the resulting stack is referred to as HTS insert. Two metal lamina are then used to encapsulate the HTS insert and are bonded with solder, forming two solder fillets at both sides of the conductor. A single mode telecommunication grade optical fiber has been integrated into the solder fillet during the lamination process. A sketch of the cross section of the SMART conductor is shown in FIG. 12, along with a scanning electron microscope (SEM) micrograph of a sample cross section.

### Experimental Results.

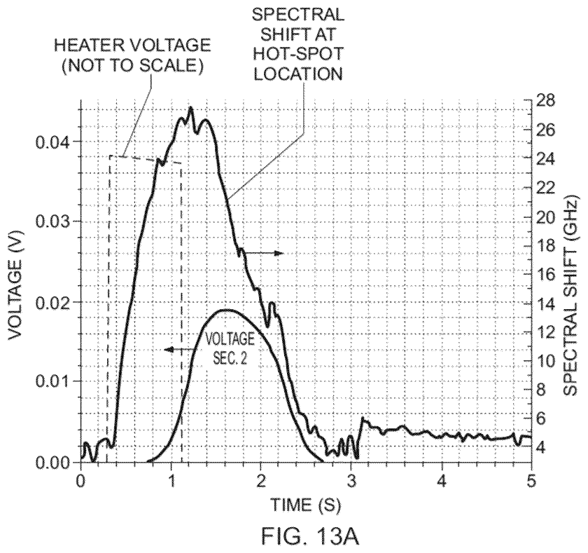

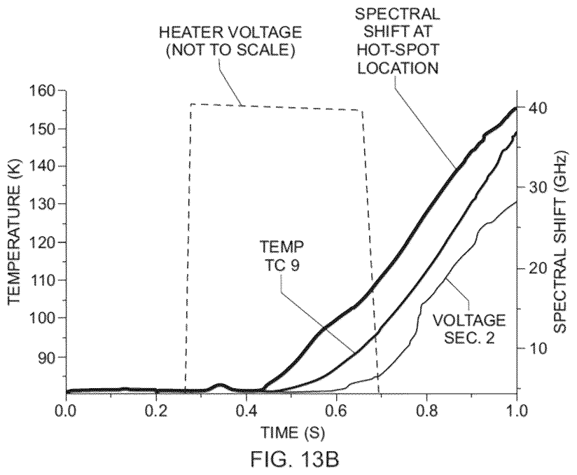

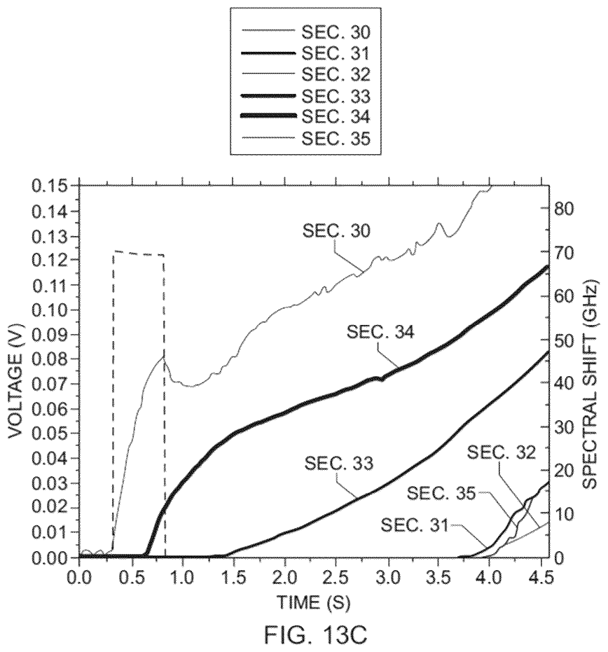

Quench measurements have been performed on all coils with co-wound fibers and samples of SMART conductor. The experimental procedure is analogous in all the experiments. A transport current is injected into the coil and linearly increased to a set value. After ramping, the current is held constant and the heater is fired to release a thermal perturbation while monitoring embedded voltage taps and interrogating optical fiber. The experiments aimed at showing the normal zone detection capability of RIOF and comparing the detection of normal zones via spectral shift to that using voltage signals. The optical interrogator used to measure the spectral shift in RIOF is the Optical Distributed Sensor Interrogator B by Luna technologies. The results of an experiment on the layer wound coil with optical fiber atop the conductor are summarized with the plots in FIGS. 13A, 13B, and 13C. The temperature at the beginning of the experiment was 77 K and the transport current was ramped to 93% of the critical current (I_{c}) that was previously measured on the coil at 77 K and self magnetic field. The voltage at the section across the heater (section 2) is plotted as a function of time along with the spectral shift measured by the optical fiber at the hot spot location (location of the maximum spectral shift). The square wave is the heater pulse that is used to initiate the normal zone. It can be noted that the spectral shift signal anticipates the voltage by about 250 ms due to the fact that the voltage starts increasing only when the local temperature exceeds the current sharing temperature (temperature at which the transport current starts to flow in the normal material within the conductor) whereas temperature changes of any magnitude can be detected by the spectral shift. Results from an experimental run that used the Bi-2223 layer wound coil with optical fiber along conductor edge are shown in FIG. 13 B.

In this case the highest temperature on the coil, just before the experiment, was 87.2 K and the transport current was increased and held at 126 A (90% Ic). The plot includes data from a thermocouple (TC 9) that is attached on the heater, voltage measured by the voltage tap that is across the heater section and the spectral shift at the hot spot location. In this case too, the spectral shift is the first signal to rise after the thermal perturbation. In all aforementioned experiments the spectral shift was measured with a spatial resolution of 5 mm and a 30 ms temporal resolution. Experiments using the pancake coil confirmed the previous trend. The results from this run are shown in FIG. 13C and include plots of voltage signals measured by all the voltage taps as well as the spectral shift measured by RIOF, with a 2.6 mm spatial resolution and 40 ms temporal resolution. In this experiment the transport current was 400 A and the initial temperature, before the thermal perturbation, was 20 K. This fiber-conductor configuration generated a spectral shift response within one time cycle from the thermal perturbation.

Optical fiber distributed sensors, interrogated via Rayleigh backscattering, have been used to detect normal zones into superconducting magnets via integration into small layer wound and pancake coils wound with HTS. RIOF showed a much earlier detection of thermal perturbations than voltage signals did. Optical fibers are also immune to electromagnetic noise and therefore are not affected by the same level of noise that can be present in applications.

Experiments at temperatures as low as 20 K have shown that the sensitivity of RIOF to thermal perturbation is adequate to detect an incipient quench.

It should be understood that the disclosure of a range of values is a disclosure of every numerical value within that range, including the end points. It should also be appreciated that some components, features, and/or configurations may be described in connection with only one particular embodiment, but these same components, features, and/or configurations can be applied or used with many other embodiments and should be considered applicable to the other embodiments, unless stated otherwise or unless such a component, feature, and/or configuration is technically impossible to use with the other embodiment. Thus, the components, features, and/or configurations of the various embodiments can be combined together in any manner and such combinations are expressly contemplated and disclosed by this statement.

It will be apparent to those skilled in the art that numerous modifications and variations of the described examples and embodiments are possible considering the above teachings of the disclosure. The disclosed examples and embodiments are presented for purposes of illustration only. Other alternate embodiments may include some or all of the features disclosed herein. Therefore, it is the intent to cover all such modifications and alternate embodiments as may come within the true scope of this invention, which is to be given the full breadth thereof.

It should be understood that modifications to the embodiments disclosed herein can be made to meet a particular set of design criteria. Therefore, while certain exemplary embodiments of the apparatuses, devices, components, and methods of using and making the same disclosed herein have been discussed and illustrated, it is to be distinctly understood that the invention is not limited thereto but may be otherwise variously embodied and practiced within the scope of the following claims.

### REFERENCES

The following references are incorporated herein by reference in their entireties.
[1] Markiewicz, W. D., Miller, J. R., Schwartz, J., Trociewitz, U. P., and Weijers, H. W., “Perspective on a superconducting 30 T/1.3 GHZ NMR spectrometer magnet,” IEEE Transactions on Applied Superconductivity, 16 (2), 1523-1526 (2006).
[2] Miao, H., Marken, K. R., Meinesz, M., Czabaj, B., Hong, S., Twin, A., Noonan, P., Trociewitz, U. P., and Schwartz, J., “High field insert coils from Bi-2212/Ag round wires,” IEEE Transactions on Applied Superconductivity, 17 (2), 2262-2265 (2007).
[3] Schwartz, J., Effio, T., Liu, X., Le, Q. V., Mbaruku, A. L., Schneider-Muntau, H. J., Shen, T., Song, H., Trociewitz, U. P., Wang, X., and Weijers, H. W., “High field superconducting solenoids via high temperature superconductors,” IEEE Transactions on Applied Superconductivity, 18 (2), 70-81 (2008).
[4] Schwartz, J., Hunte, F., Chan, W., Gou, X., Liu, X., Phillips, M., Le, Q., Naderi, G., Turenne, M., and Ye, L., “Status of high temperature superconductor based magnets and the conductors they depend upon,” arXiv preprint arXiv:1108.1634, (2011).
[5] Rossi, L., [LHC upgrade plans: options and strategy], (2011).
[6] Song, H., and Schwartz, J., “Stability and Quench Behavior of YBa2Cu3O7-x Coated Conductor at 4.2 K, Self-Field,” IEEE Transactions on Applied Superconductivity, 19(5), 3735-3743 (2009).
[7] Trillaud, F., Palanki, H., Trociewitz, U. P., Thompson, S. H., Weijers, H. W., and Schwartz, J., “Normal zone propagation experiments on HTS composite conductors,” Cryogenics, 43(3-5), 271-279(2003).
[8] Wang, X., Trociewitz, U. P., and Schwartz, J., “Near-adiabatic quench experiments on short YBa2Cu3O7-delta coated conductors,” Journal of Applied Physics, 101(5), (2007).
[9] Wang, X. R., Caruso, A. R., Breschi, M., Zhang, G. M., Trociewitz, U. P., Weijers, H. W., and Schwartz, J., “Normal zone initiation and propagation in Y—Ba—Cu—O coated conductors with Cu stabilizer,” IEEE Transactions on Applied Superconductivity, 15(2), 2586-2589 (2005).
[10] Cheng, L., Nieuwland, R., Toet, P., and Agovic, K., “Fiber Bragg grating sensors,” Proceedings 2010 Annual Symposium of the IEEE Photonics Society. 149-152 (2010).
[11] Hunte, F., Song, H., Schwartz, J., Johnson, R., and Turenne, M., “Fiber Bragg optical sensors for YBCO applications,” Proc. Particle Accelerator Conference. (2009).
[12] Turenne, M., Johnson, R., Hunte, F., Schwartz, J., and Song, H., “Multi-purpose fiber optic sensors for high temperature superconducting magnets,” Symposium on Fusion Engineering. 1-4 (2009).
[13] Chiuchiolo, A., Bajko, M., Perez, J., Bajas, H., Consales, M., Giordano, M., Breglio, G., and Cusano, A., “Fiber Bragg Grating Cryosensors for Superconducting Accelerator Magnets,” Photonics Journal, IEEE, 6(6), 1-10 (2014).
[14] Gifford, D. K., Kreger, S. T., Sang, A. K., Froggatt, M. E., Duncan, R. G., Wolfe, M. S., and Soller, B. J., “Swept-wavelength interferometric interrogation of fiber Rayleigh scatter for distributed sensing applications.” 67700F-67700F-9 (2007).
[15] Scurti, F., Ishmael, S., Flanagan, G., and Schwartz, J., “Quench detection for high temperature superconductor magnets: a novel technique based on Rayleigh-backscattering interrogated optical fibers,” Superconductor Science and Technology, 29(3), 03LT01 (2016).
[16] Scurti, F., Sathyamurthy, S., Rupich, M., and Schwartz, J., “Self-monitoring “SMART” REBCO coated conductor via integrated optical fibers,” Superconductor Science and Technology, (Submitted 2016).
[17] Scurti, Federico, Schwartz, Justin, “Optical fiber distributed sensing for high temperature superconductor magnets” Proc. SPIE 10323, 25th International Conference on Optical Fiber Sensors, 103238Q (23 Apr. 2017); doi:10.1117/12.2265947

What is claimed is:

1. A magnet apparatus, comprising:
a winding;
a sensing module configured to measure strain and/or temperature experienced by the winding; and
a magnet management unit including a processor and memory having instructions stored thereon that when executed will cause the processor to:
detect a change in strain and/or temperature experienced by the winding;
calculate a reduction of transport current that, if applied to the winding, will prevent material degradation of the winding due to strain and/or heat; and
generate a signal indicative of the calculated reduction of transport current, the signal configured to be transmitted to a current power supply.

2. The magnet apparatus of claim 1, wherein:
the instructions cause the processor to calculate the reduction of transport current based output of the sensing module.

3. The magnet apparatus of claim 2, wherein:
the sensing module is configured to generate an optical output that is proportional to the strain and/or the temperature.

4. The magnet apparatus of claim 1, further comprising:
the current power supply.

5. The magnet apparatus of claim 4, wherein:
the current power supply is configured to adjust the transport current based on the calculated reduction of transport current.

6. The magnet apparatus of claim 4, wherein:
the current power supply is a fast current power supply.

7. The magnet apparatus of claim 1, wherein:
the sensing module includes an optical fiber.

8. The magnet apparatus of claim 1, wherein:
the magnet apparatus is configured as a superconducting magnet.

9. The magnet apparatus of claim 1, wherein:
the magnet apparatus is configured as a high-temperature superconductor (HTS) magnet.

10. The magnet apparatus of claim 1, wherein:
the winding includes superconducting material.

11. The magnet apparatus of claim 10, wherein:
the superconducting material within the magnet is made of niobium-titanium (NbTi), niobium-tin (Nb₃Sn), yttrium-barium-copper-oxide (YBa₂Cu₃O₇₋ₓ), Bi₂Sr₂Ca₂Cu₃Ox, Bi₂Sr₂Ca₁Cu₂Ox, and/or MgB₂.

12. The magnet apparatus of claim 1, wherein:
the sensing module includes an optical fiber and an optical interrogator.

13. The magnet apparatus of claim 7, wherein:
the optical fiber is embedded or co-wound with the winding.

14. The magnet apparatus of claim 7, wherein:
the sensing module is configured to generate an optical signal based on a technique involving Fiber Bragg Grating, Rayleigh scattering, Brillouin scattering, distributed acoustic sensing, and/or Raman scattering.

15. The magnet apparatus of claim 12, wherein:
the optical fiber is embedded or co-wound with the winding; and
wherein the optical interrogator is configured to measure spectral shift from the optical fiber as a function of time and position along the winding.

16. The magnet apparatus of claim 15, wherein:
the instructions cause the processor to detect the change in strain and/or temperature based on the measured spectral shift being proportional to change in strain and/or temperature experienced by the winding.

17. The magnet apparatus of claim 15, wherein:
the instructions cause the processor to calculate the reduction of transport current based on a predetermined time window of an optical signal detected by the optical interrogator.

18. The magnet apparatus of claim 17, wherein:
the instructions cause the processor to calculate the reduction of transport current that is associated with the measured spectral shift.

19. The magnet apparatus of claim 18, wherein:
the reduction of transport current will, when applied, result in a current transport value that is a maximum transport current that suppresses formation or propagation of at least one normal zone but also minimizes deviation from nominal operation of the magnet apparatus.

20. The magnet apparatus of claim 16, wherein:
the instructions cause the processor to calculate the reduction of transport current that corresponds to the measured spectral shift, the calculation being at a predetermined time, a continuous basis, or a periodic basis; and
the instructions cause the processor to generate the signal indicative of the calculated reduction of transport current at a predetermined time, a continuous basis, or a periodic basis.

21. A magnet apparatus, comprising:
a winding;
an optical sensing module configured to generate an optical signal indicative of strain and/or temperature experienced by the winding; and
a magnet management unit including a processor and memory having instructions stored thereon that when executed will cause the processor to:
receive the optical signal; and
generate a modulating signal for modulating transport current of a current power supply based on the optical signal.
